(19) United States
(12) Patent Application Publication
(10) Pub. No.: US 2024/0411973 A1
(43) Pub. Date: Dec. 12, 2024

(54) CIRCUIT LAYOUT CHECKING METHOD AND CIRCUIT LAYOUT CHECKING SYSTEM

(71) Applicant: REALTEK SEMICONDUCTOR CORPORATION, Hsinchu (TW)

(72) Inventors: I-CHING TSAI, Hsinchu (TW); CHIH-WEI LIN, Hsinchu (TW)

(21) Appl. No.: 18/735,241

(22) Filed: Jun. 6, 2024

(30) Foreign Application Priority Data
Jun. 12, 2023 (TW) 112121908

(51) Int. Cl. G06F 30/343

(52) U.S. Cl. CPC G06F 30/343

(57) ABSTRACT

A circuit layout checking method includes: determining whether there is only a first layout pattern and/or a second layout pattern corresponding to a filler cell or a second gate array cell exist in a region extending outward from the first layout pattern corresponding to a first gate array cell; determining whether a first pattern corresponding to an electrical connection layer in the first layout pattern is enclosed by a second pattern corresponding to a metal layer in the first layout pattern and whether each spacing between all boundaries of the first pattern and those of the second pattern is not less than a predetermined distance; and if there is only the first and/or second layout patterns in the first region and if the first pattern is enclosed by the second pattern and each spacing is not less than the predetermined distance, generating data indicating layout design of an integrated circuit.

### BACKGROUND OF THE DISCLOSURE

### 1. Field of the Disclosure

The present disclosure relates to a circuit layout checking system, especially to circuit layout checking system and method able to avoid remaking masks during the fabrication of integrated circuits.

### 2. Description of Related Art

During the chip design phase, operations of functional cells (or units) in an integrated circuit may be modified through an Engineering Change Order (ECO). On the other hand, with the development of semiconductor processes, the size of transistors becomes smaller, making it challenging for the patterns realized through lithography to completely match the expected designs. To address these issues, optical proximity correction (OPC) can be employed to modify or adjust masks to correct inaccurate patterns. Practically, integrated circuits after ECO require OPC. In this phase, the Re-Tape Out (RTO) rules can be used to identify which layout patterns in the integrated circuit after ECO require remaking of their corresponding masks due to OPC. In some cases, structures that have not been modified after ECO may still violate the RTO rules due to OPC, such that the respective masks requires remaking or correction, thereby increasing the overall manufacturing costs.

### SUMMARY OF THE DISCLOSURE

In some aspects of the present disclosure, an object of the present disclosure is, but not limited to, provide circuit layout checking system and method able to avoid remaking masks during the fabrication of integrated circuits, so as to make an improvement to the prior art.

In some aspects of the present disclosure, a circuit layout checking method includes the following operations: determining whether only at least one of a first layout pattern or a second layout pattern exists in a first area extending outward from the first layout pattern, wherein the first layout pattern corresponds to a first logic gate array cell, and the second layout pattern corresponds to a filler cell or a second logic gate array cell; determining whether a first pattern in the first layout pattern is enclosed by a second pattern in the first layout pattern and whether a spacing between every boundary of the first pattern and every boundary of the second pattern is not less than a first predetermined distance, wherein the first pattern corresponds to an electrical connection layer, and the second pattern corresponds to a metal layer; and if only the at least one of the first layout pattern or the second layout pattern exists in the first area and if the first pattern is enclosed by the second pattern and the spacing between every boundary of the first pattern and every boundary of the second pattern is not less than the first predetermined distance, generating data indicating a layout design of an integrated circuit.

In some aspects of the present disclosure, a circuit layout checking system includes a memory circuit and a processor circuit. The memory circuit is configured to store at least one computer program code. The processor circuit is configured to execute the at least one computer program code to: determine whether only at least one of a first layout pattern or a second layout pattern exists in a first area extending outward from the first layout pattern, wherein the first layout pattern corresponds to a first logic gate array cell, and the second layout pattern corresponds to a filler cell or a second logic gate array cell; determine whether a first pattern in the first layout pattern is enclosed by a second pattern in the first layout pattern and whether a spacing between every boundary of the first pattern and every boundary of the second pattern is not less than a first predetermined distance, wherein the first pattern corresponds to an electrical connection layer, and the second pattern corresponds to a metal layer; and if only the at least one of the first layout pattern or the second layout pattern exists in the first area and if the first pattern is enclosed by the second pattern and the spacing between every boundary of the first pattern and every boundary of the second pattern is not less than the first predetermined distance, generate data indicating a layout design of an integrated circuit.

These and other objectives of the present disclosure will no doubt become obvious to those of ordinary skill in the art after reading the following detailed description of the preferred embodiments that are illustrated in the various figures and drawings

### BRIEF DESCRIPTION OF THE DRAWINGS

FIG. 1 illustrates a schematic diagram of a circuit layout checking system according to some embodiments of the present disclosure.

FIG. 2 illustrates a flowchart of a circuit layout checking method according to some embodiments of the present disclosure.

FIG. 3A illustrates a schematic diagram of a layout design according to some embodiments of the present disclosure.

FIG. 3B illustrates a schematic diagram of the layout pattern in FIG. 3A according to some embodiments of the present disclosure.

FIG. 4 illustrates a schematic diagram of a layout design according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuitry” may be a single system formed with at least one circuit, and the term “circuit” may indicate an object, which is formed with one or more transistors and/or one or more active/passive elements based on a specific arrangement, for processing signals.

As used herein, the term “and/or” includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, like elements in various figures are designated with the same reference number.

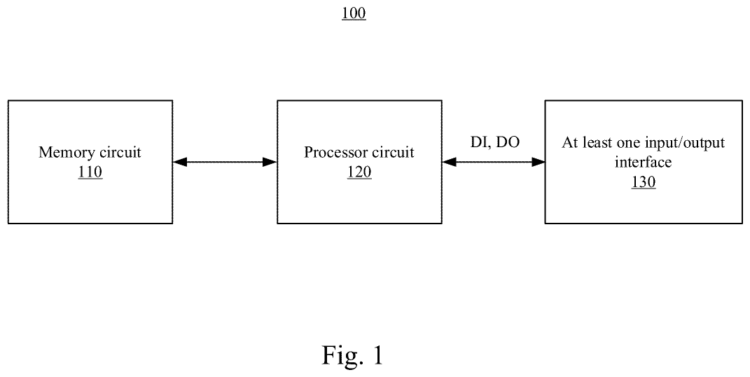

FIG. 1 illustrates a schematic diagram of a circuit layout checking system 100 according to some embodiments of the present disclosure. In some embodiments, the circuit layout checking system 100 may automatically check whether a layout design for manufacturing integrated circuits complies with predetermined layout constraints to avoid remaking masks, thereby saving overall manufacturing costs.

In some embodiments, the circuit layout checking system 100 includes a memory circuit 110, a processor circuit 120, and at least one input/output interface 130. In some embodiments, the processor circuit 120 may be, but not limited to, a central processing unit (CPU), an application-specific integrated circuit (ASIC), multiprocessors, distributed processing systems, or a suitable processing unit. Various circuits or units to implement the processor circuit 120 are within the contemplated scope of the present disclosure.

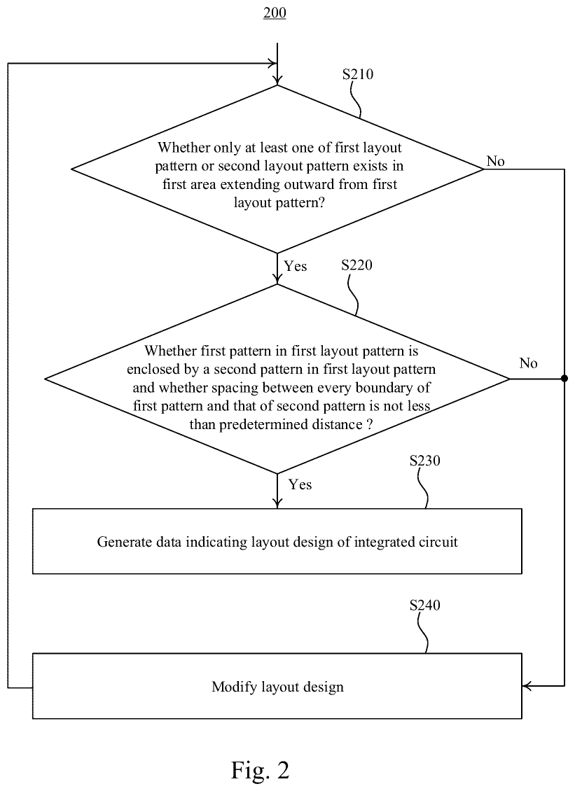

The memory circuit 110 may store at least one computer program code, which may be utilized to assist in designing integrated circuits. For example, the at least one computer program code may be encoded by multiple instruction sets, where the multiple instruction sets are employed to check if layout patterns in the integrated circuit comply with the aforementioned predetermined layout constraints. The processor circuit 120 may execute the at least one computer program code stored in the memory circuit 110, and the operations of checking layout patterns can be automatically performed. In some embodiments, the at least one computer program code may be integrated with existing computer-aided design tools. In some embodiments, the memory circuit 110 may be a non-volatile computer-readable storage medium that stores executable instructions for performing operations shown in FIG. 2. In some embodiments, the non-volatile computer-readable storage medium may include, but is not limited to, semiconductor or solid-state memory, magnetic tape, removable computer disk, random access memory (RAM), read-only memory (ROM), hard disk, and/or optical disk. In some embodiments, the aforementioned optical disk may include, but is not limited to, a CD-ROM, a CD-R/W, and/or a DVD.

The at least one input/output interface 130 may receive multiple data and/or commands, where those data and/or commands may be issued by a device operated by circuit designer or layout designer. Thus, the circuit layout checking system 100 may be controlled by commands received through the at least one input/output interface 130. In some embodiments, the at least one input/output interface 130 may include a display configured to show the status of program code execution. In some embodiments, the at least one input/output interface 130 may include, but is not limited to, a graphical user interface, keyboard, mouse, trackball, touchscreen, cursor direction keys, or any combination thereof, to communicate information and multiple commands to the processor circuit 120.

In some embodiments, the processor circuit 120 may receive data DI through the at least one input/output interface 130, where the data DI is to indicate the layout design of an integrated circuit. The processor circuit 120 may execute the at least one computer program code in the memory circuit 110 to analyze the data DI to obtain layout patterns in the data DI and perform operations shown in FIG. 2, to check if the layout patterns in the data DI comply with the predetermined layout constraints. If all of the layout patterns in data DI comply with the predetermined layout constraints, the processor circuit 120 may output the data DI as data DO and store the data DO in the memory circuit 110. Thus, circuit designer(s) or layout designer(s) may obtain the data DO through the at least one input/output interface 130 and provide the data DO to a foundry for manufacturing the integrated circuit corresponding to the layout design.

In some embodiments, the term “layout pattern” or “pattern” broadly refers to planar geometric shapes that are utilized in computer-aided design tools to represent the layout design of integrated circuits and are corresponding to various components of the integrated circuit, which may be but not limited to, metal layers, electrical connection layers, oxide layers, and/or semiconductor layers.

FIG. 2 illustrates a flowchart of a circuit layout checking method 200 according to some embodiments of the present disclosure. In some embodiments, the circuit layout checking method 200 may be executed by the circuit layout checking system 100 shown in FIG. 1.

In operation S210, whether only at least one of a first layout pattern or a second layout pattern exists in a first area extending outward from the first layout pattern is determined, in which the first layout pattern corresponds to a first logic gate array cell, and the second layout pattern corresponds to a filler cell or a second logic gate array cell. If only the first and/or second layout patterns exist in the first area, operation S220 is performed. Alternatively, if other layout patterns exist in the first area, operation S240 is performed.

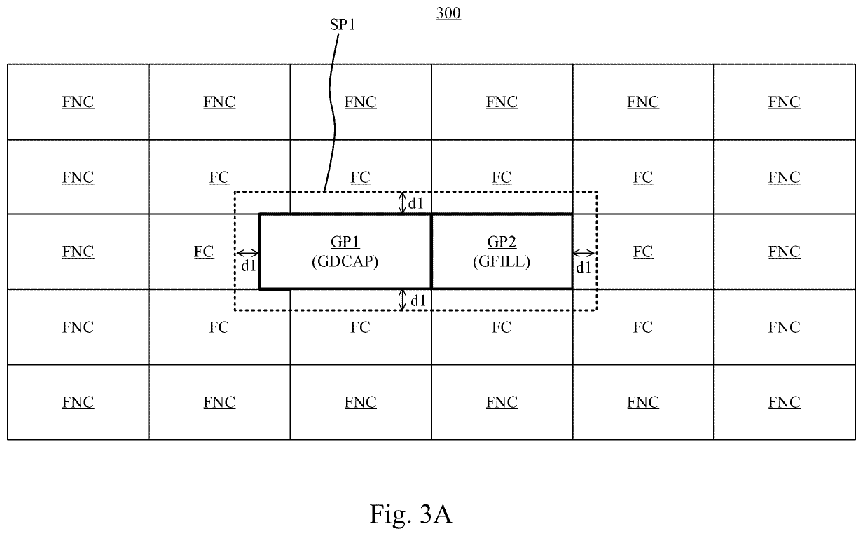

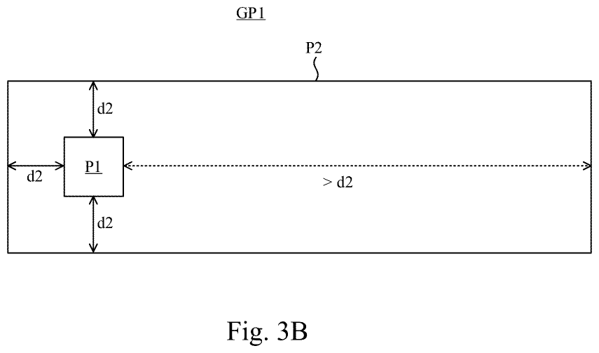

To illustrate operation S210, reference is made to FIG. 3A, which illustrates a schematic diagram of a layout design 300 according to some embodiments of the present disclosure. The layout design 300 shown in FIG. 3A may be a part of layout pattern of the integrated circuit. The processor circuit 120 in FIG. 1 may analyze the data DI to obtain information about layout patterns in the layout design 300. For example, the layout design 300 includes layout patterns GP1 and GP2 corresponding to logic gate array cells, layout patterns FC corresponding to filler cells, and layout patterns FNC corresponding to functional cells. In some embodiments, the aforementioned logic gate array cells may be programmable logic gate array cells utilized for engineering change orders (ECO). For example, the logic gate array cells may include at least one standard cell circuit that may be implemented with a digital circuit capable of executing one or more logic functions. Before the ECO, the inputs and outputs of these logic gate array cells are not coupled to the aforementioned functional cells. After the ECO, the inputs and outputs of some logic gate array cells may be adjusted to be coupled to node(s) in functional cells to correct or adjust the operation and/or signal transmission of these functional cells to comply with design requirements. In some embodiments, the logic gate array cells may be set to operate as a decoupling unit (decap cells; marked as GDCAP in the figure), which may be utilized to maintain voltage stability in the system. In some embodiments, the logic gate array cells may be set to operate as filler cells (marked as GFILL in the figure), which may be used to increase the continuity between power rails. On the other hand, the filler cells corresponding to the layout patterns FC may be, but not limited to, filler cells implemented with standard cell circuits or filler cells implemented with logic gate array cells. In some embodiments, the functional cells corresponding to multiple layout patterns FNC may be main circuits in the integrated circuit, which may be configured to perform a specific logic operation.

As shown in FIG. 3A, only layout patterns GP1, GP2, and FC corresponding to logic gate array cells and/or filler cells exist within an area SP1 (shown with dashed lines) extending outward from the layout patterns GP1 and GP2. In other words, the layout patterns FNC corresponding to functional cells are not located within the area SP1. Thus, the layout patterns FNC may maintain a sufficient distance from the layout patterns GP1 and GP2 (corresponding to logic gate array cells for ECO), avoiding the need to modify masks due to violations of retape-out (RTO) rules after ECO. In some embodiments, the area SP1 is formed by extending a predetermined distance d1 outward from all boundaries of the layout patterns GP1 and/or GP2. In this example, as the layout patterns GP1 and GP2 are arranged adjacent to each other (and contact each other), the layout patterns GP1 and GP2 may be merged and considered as the same layout pattern, and a predetermined distance d1 is extended outward from all the boundaries of this layout pattern to define the area SP1. In other embodiments, if the layout patterns GP1 and GP2 are not adjacent arranged, a first area may be defined by extending the predetermined distance d1 outward from all the boundaries of the layout pattern GP1, and a second area may be defined by extending the predetermined distance d1 outward from all the boundaries of the layout pattern GP2, and then whether only layout patterns corresponding to filler cells and/or logic gate array cells exist within the first and second areas are respectively determined.

In some embodiments, the predetermined distance d1 may be about between 0.19 micrometers (μm) to 0.3 μm. In some embodiments, the predetermined distance d1 may be about 0.25 μm or about 0.24 μm. These values of the predetermined distance d1 are given for illustrative purposes and may be set according to semiconductor process, and thus the present disclosure is not limited thereto. In some embodiments, the value of the predetermined distance d1 may be ±5%, ±10%, or ±20% of the above-mentioned value range or specific values.

With continued reference to FIG. 2, in operation S220, whether a first pattern in the first layout pattern is enclosed by a second pattern in the first layout pattern and whether a spacing between every boundary of the first pattern and that of the second pattern is not less than (i.e., equal to or greater than) a predetermined distance are determined, in which the first pattern corresponds to an electrical connection layer, and the second pattern corresponds to a metal layer.

To illustrate operation S220, reference is made to FIG. 3B, which illustrates a schematic diagram of the layout pattern GP1 in FIG. 3A according to some embodiments of the present disclosure. The layout pattern GP1 in FIG. 3B may be a part pattern in the layout pattern GP1 of FIG. 3A. In some embodiments, the layout pattern GP1 may include a pattern P1 corresponding to an electrical connection layer and a pattern P2 corresponding to a metal layer. In some embodiments, the electrical connection layer may include a layer connecting to transistors, such as a contact layer. In some embodiments, the electrical connection layer may include a layer connecting to different metal layers, such as a via. In some embodiments, the metal layer may be a connection layer adjusted in ECO and may be the top metal layer. For example, the connection layer may be the first metal layer (commonly marked as M1 in layout tool) or the second metal layer (commonly marked as M2).

As previously mentioned, the inputs or outputs of the logic gate array cells utilized for ECO are not coupled to the functional cells. After ECO, the inputs or outputs of some logic gate array cells may be adjusted to be coupled to the functional cells. These adjustments are usually realized by modifying the layout and/or connection relations of the aforementioned metal layer and electrical connection layer. By performing operation S220 to check the patterns P1 and P2 which respectively correspond to the electrical connection layer and metal layer, it is able to prevent the aforementioned adjustments from violating RTO rules. In some embodiments, the check conditions set in operation S220 mainly apply to the electrical connection layer at the line end of the metal layer, but the present disclosure is not limited thereto.

As shown in FIG. 3B, the pattern P1 is enclosed by the pattern P2, and the spacing between each boundary of the pattern P1 and each boundary of the pattern P2 is greater than or equal to a predetermined distance d2. In some embodiments, the predetermined distance d2 may be about between 0.004 μm and 0.02 μm. In some embodiments, predetermined distance d2 may be about 0.015 μm or 0.005 μm. These values of the predetermined distance d2 are given for illustrative purposes and may be adjusted according to semiconductor process settings, and the present disclosure is not limited thereto. In some embodiments, the value of the predetermined distance d2 may be ±5%, ±10%, or ±20% of the aforementioned value range or specific values. If the layout design 300 complies with the check conditions set in operations S210 and S220 (which may be equivalent to the aforementioned predetermined layout constraints), it may ensure that there is no need to remake the masks corresponding to the layout design 300 after ECO or that the number of the masks to be remade can be reduced. As a result, it is able to save overall manufacturing costs. Similarly, operation S220 is also performed to check the layout pattern GP2 in FIG. 3A.

With continued reference to FIG. 2, in operation S230, data indicating the layout design of an integrated circuit is generated. In operation S240, the layout design is modified. For example, if the layout design 300 complies with the predetermined layout constraints set in operations S210 and S220, it indicates that all layout patterns in the layout design 300 comply with the predetermined layout constraints. Under this condition, the current layout design 300 is stored as data DO, which is to be provided to the foundry for manufacturing the integrated circuit corresponding to the layout design 300. Alternatively, if the layout design 300 does not comply with the predetermined layout constraints in operations S210 or S220, the layout design 300 can be modified by using automated routing tools or by notifying the layout designer, and the modified layout design 300 is then re-checked.

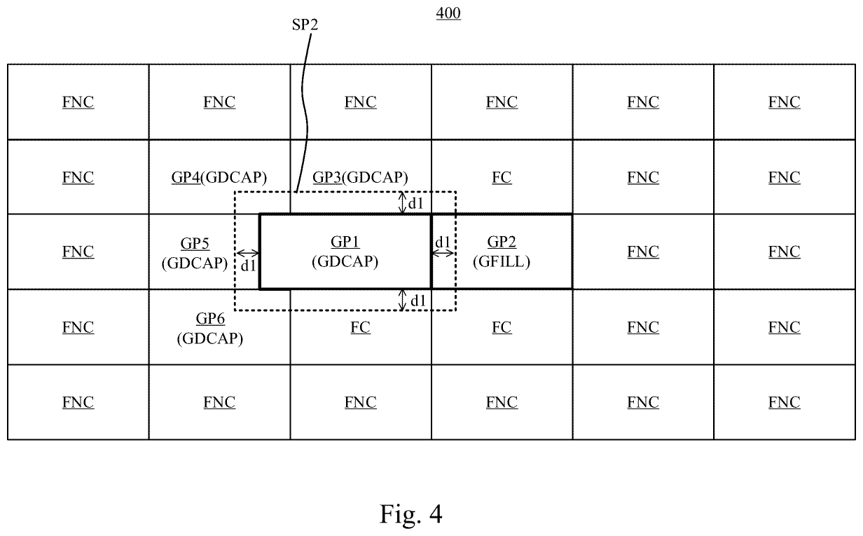

In some embodiments, the aforementioned examples mainly illustrate the layout checks performed during the process of filling the layout design 300 with layout patterns corresponding to logic gate array cells, but the present disclosure is not limited thereto. In some embodiments, if the layout design corresponding to the data DI has already been filled with logic gate array cells, the circuit layout checking method 200 may further include the following operations before performing ECO: selecting a corresponding layout pattern from third layout patterns, where a second area extending outward from the corresponding layout pattern does not include a fourth layout pattern, the third layout patterns correspond to third logic gate array cells, and the fourth layout pattern corresponds to a functional cell; and the corresponding layout pattern is modified to perform the ECO. To illustrate the above operations, reference is made to FIG. 4, which illustrates a schematic diagram of a layout design 400 according to some embodiments of the present disclosure. The processor circuit 120 in FIG. 1 may analyze the data DI to obtain information about layout patterns in the layout design 400. For example, different from the layout design 300, the layout design 400 further includes layout patterns GP3-GP6 corresponding to logic gate array cells (which may be configured as decoupling units, marked as GDCAP) and more layout patterns FNC corresponding to functional cells.

In this example, layout patterns GP1-GP6 all correspond to logic gate array cells, and layout patterns GP3-GP6 are arranged adjacent to layout patterns corresponding to functional cells. To avoid the distance between logic gate array cells used in ECO and functional cells being too close, appropriate logic gate array cells may be selected through the aforementioned operations to avoid violating RTO rules. For example, in the example of FIG. 4, as no layout patterns corresponding to functional cells exist in the area SP2 extending outward from the layout pattern GP1, the layout pattern GP1 may be selected for ECO. The aforementioned area SP2 may be an area formed by extending a predetermined distance d1 outward from all boundaries of layout pattern GP1 (similar to area SP1 in FIG. 3A). Thus, as there is a sufficient distance between the layout pattern GP1 corresponding to the logic gate array cell and the layout pattern corresponding to functional cells, the modified layout pattern GP1 after ECO will not violate RTO rules, thereby avoiding the need to remake masks. Then, after ECO, the processor circuit 120 may output the modified layout design 400 as the data DO (i.e., operation S230).

In some embodiments, operations shown in FIG. 4 may be performed before operation S230, and may be performed in parallel with operations S210 and S220, but the present disclosure is not limited thereto. Operations in the circuit layout checking method 200 can be understood with reference to descriptions of above embodiments, and thus repetitious descriptions are not further given herein. The above description of operations includes exemplary operations, but the operations are not necessarily performed in the order described above. Operations of the circuit layout checking method 200 may be added, replaced, changed order, and/or eliminated, or may be performed simultaneously or partially simultaneously as appropriate, in accordance with the spirit and scope of various embodiments of the present disclosure.

As described above, the circuit layout checking method and system provided in some embodiments of the present disclosure may check whether the layout design complies with predetermined layout constraints, in order to save on ECO costs and reduce overall manufacturing expenses.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically comprise transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely the preferred embodiments of the present disclosure, without any intention to limit the scope of the present disclosure thereto. Various equivalent changes, alterations, or modifications based on the claims of the present disclosure are all consequently viewed as being embraced by the scope of the present disclosure.

What is claimed is:

1. A circuit layout checking method, comprising:
determining whether only at least one of a first layout pattern or a second layout pattern exists in a first area extending outward from the first layout pattern, wherein the first layout pattern corresponds to a first logic gate array cell, and the second layout pattern corresponds to a filler cell or a second logic gate array cell;
determining whether a first pattern in the first layout pattern is enclosed by a second pattern in the first layout pattern and whether a spacing between every boundary of the first pattern and every boundary of the second pattern is not less than a first predetermined distance, wherein the first pattern corresponds to an electrical connection layer, and the second pattern corresponds to a metal layer; and
if only the at least one of the first layout pattern or the second layout pattern exists in the first area and if the first pattern is enclosed by the second pattern and the spacing between every boundary of the first pattern and every boundary of the second pattern is not less than the first predetermined distance, generating data indicating a layout design of an integrated circuit.

2. The circuit layout checking method of claim 1, wherein the electrical connection layer comprises a contact or a via.

3. The circuit layout checking method of claim 1, wherein each of the first logic gate array cell and the second logic gate array cell is a programmable logic gate array cell utilized for an engineering change order.

4. The circuit layout checking method of claim 1, wherein the first area is an area formed by extending a second predetermined distance outward from all boundaries of the first layout pattern.

5. The circuit layout checking method of claim 4, wherein the second predetermined distance is between 0.19 micrometers to 0.3 micrometers.

6. The circuit layout checking method of claim 1, wherein the first predetermined distance is between 0.004 micrometers to 0.02 micrometers.

7. The circuit layout checking method of claim 1, wherein the metal layer is a connection layer to be adjusted in an engineering change order.

8. The circuit layout checking method of claim 1, further comprising:
selecting a corresponding layout pattern from a plurality of third layout patterns, wherein a second area extending outward from the corresponding layout pattern does not comprise a fourth layout pattern, the third layout patterns respectively correspond to a plurality of third logic gate array cells, and the fourth layout pattern corresponds to a functional cell; and
modifying the corresponding layout pattern perform an engineering change order.

9. The circuit layout checking method of claim 8, wherein the second area is an area formed by extending a second predetermined distance outward from all boundaries of the fourth layout pattern.

10. The circuit layout checking method of claim 9, wherein the second predetermined distance is between 0.19 micrometers to 0.3 micrometers.

11. A circuit layout checking system, comprising:
a memory circuit configured to store at least one computer program code; and
a processor circuit configured to execute the at least one computer program code to:
determine whether only at least one of a first layout pattern or a second layout pattern exists in a first area extending outward from the first layout pattern, wherein the first layout pattern corresponds to a first logic gate array cell, and the second layout pattern corresponds to a filler cell or a second logic gate array cell;
determine whether a first pattern in the first layout pattern is enclosed by a second pattern in the first layout pattern and whether a spacing between every boundary of the first pattern and every boundary of the second pattern is not less than a first predetermined distance, wherein the first pattern corresponds to an electrical connection layer, and the second pattern corresponds to a metal layer; and
if only the at least one of the first layout pattern or the second layout pattern exists in the first area and if the first pattern is enclosed by the second pattern and the spacing between every boundary of the first pattern and every boundary of the second pattern is not less than the first predetermined distance, generate data indicating a layout design of an integrated circuit.

12. The circuit layout checking system of claim 11, wherein the electrical connection layer comprises a contact or a via.

13. The circuit layout checking system of claim 11, wherein the first logic gate array cell is a programmable logic gate array cell utilized for an engineering change order.

14. The circuit layout checking system of claim 11, wherein the first area is an area formed by extending a second predetermined distance outward from all boundaries of the first layout pattern.

15. The circuit layout checking system of claim 14, wherein the second predetermined distance is between 0.19 micrometers to 0.3 micrometers.

16. The circuit layout checking system of claim 11, wherein the first predetermined distance is between 0.004 micrometers to 0.02 micrometers.

17. The circuit layout checking system of claim 11, wherein the metal layer is a connection layer to be adjusted in an engineering change order.

18. The circuit layout checking system of claim 11, wherein the processor circuit is further configured to execute the at least one computer program code to:
select a corresponding layout pattern from a plurality of third layout patterns, wherein a second area extending outward from the corresponding layout pattern does not comprise a fourth layout pattern, the third layout patterns respectively correspond to a plurality of third logic gate array cells, and the fourth layout pattern corresponds to a functional cell; and
modify the corresponding layout pattern perform an engineering change order.

19. The circuit layout checking system of claim 18, wherein the second area is an area formed by extending a second predetermined distance outward from all boundaries of the fourth layout pattern.

20. The circuit layout checking system of claim 19, wherein the second predetermined distance is between 0.19 micrometers to 0.3 micrometers.
